(19) United States
(12) Patent Application Publication
(10) Pub. No.: US 2016/0225462 A1
(43) Pub. Date: Aug. 4, 2016

(54) SHIFT REGISTER CIRCUIT

(71) Applicant: Japan Display Inc., Minato-ku (JP)

(72) Inventor: Kenji HARADA, Minato-ku (JP)

(73) Assignee: Japan Display Inc., Minato-ku (JP)

(21) Appl. No.: 15/001,778

(22) Filed: Jan. 20, 2016

(30) Foreign Application Priority Data
Jan. 29, 2015 (JP) 2015-015698

(51) Int. Cl. G11C 19/28

(52) U.S. Cl. CPC G11C 19/28

(57) ABSTRACT

A shift register circuit is provided that can reduce the number of elements of transistors T.

A signal generating circuit in each stage includes a set terminal receiving an output signal of the preceding stage, D1 having an anode connected to the set terminal, a reset terminal receiving an output signal of the next stage, T1 having a gate connected to the reset terminal, T1 connecting a cathode of D1 to VGL when the output signal from the next stage is input to the gate, T2 having a source connected to an output terminal and a drain receiving a clock signal, T3 having a source connected to VGL and a drain connected to the output terminal, an inverter circuit including T4 and T5, T6 having a source connected to a gate of T2, a drain connected to the cathode of D1 and a gate connected to VGH, and D2 having an anode connected to VGH. The input point of the inverter circuit is connected to the cathode of D1, the output point is connected to a gate of T3, and the high potential connection point is connected to a cathode of D2.

### CROSS-REFERENCE TO RELATED APPLICATIONS

This application is based upon and claims the benefit of priority from the prior Japanese Patent Application No. 2015-15698, filed on Jan. 29, 2015; the entire contents of which are incorporated herein by reference.

### FIELD

Embodiments described herein relate generally to a shift register circuit.

### BACKGROUND

There is a conventional method for reducing the electric power of a shift register circuit by configuring one signal generating circuit including an RS flip flop and a trigger generating circuit, setting the signal generating circuit by an output from a signal generating circuit in the preceding stage, and resetting the signal generating circuit by an output from a signal generating circuit in the next stage to reduce the load of the wiring capacity of a clock signal.

However, since the number of transistor elements constituting the signal generating circuit in each stage is large in such a shift register circuit, the layout area of the circuit becomes large, thereby making it difficult to narrow a frame of a liquid crystal display device in a case that the shift register circuit is applied to a gate circuit of the liquid crystal display device or the like.

Accordingly, embodiments of the invention address the above problem and provide a shift register circuit that can reduce the number of transistor elements.

### BRIEF DESCRIPTION OF THE DRAWINGS

FIG. 1 is a circuit diagram illustrating a shift register circuit according to an embodiment.

FIG. 2 is a circuit diagram illustrating an n-th signal generating circuit.

FIG. 3 is a waveform diagram of the signal generating circuit.

FIG. 4 is a circuit diagram illustrating a signal generating circuit according to a modification.

### DETAILED DESCRIPTION

According to embodiments, a shift register circuit includes N signal generating circuits each configured to generate a pulsed output signal. The n-th (where 1≦n≦N) signal generating circuit of the N signal generating circuits includes a set terminal receiving an output signal of the (n−1)-th signal generating circuit, a first diode having an anode connected to the set terminal, a reset terminal configured to receive an output signal of the (n+1)-th signal generating circuit, a first N-channel transistor having a gate connected to the reset terminal, the first N-channel transistor configured to connect a cathode of the first diode to a low potential power source when the output signal of the (n+1)-th signal generating circuit is input to the gate, a second N-channel transistor having a source connected to an output terminal and a drain configured to receive a clock signal, a third N-channel transistor having a source connected to the low potential power source and a drain connected to the output terminal, a CMOS inverter circuit including a fourth P-channel transistor and a fifth N-channel transistor, a sixth N-channel transistor having a source connected to a gate of the second transistor, a drain connected to the cathode of the first diode, and a gate connected to a high potential power source, and a second diode having an anode connected to the high potential power source. An input point of the CMOS inverter circuit is connected to the cathode of the first diode. An output point of the CMOS inverter circuit is connected to a gate of the third transistor. A high potential connection point of the CMOS inverter circuit is connected to a cathode of the second diode. A low potential connection point of the CMOS inverter circuit is connected to the low potential power source.

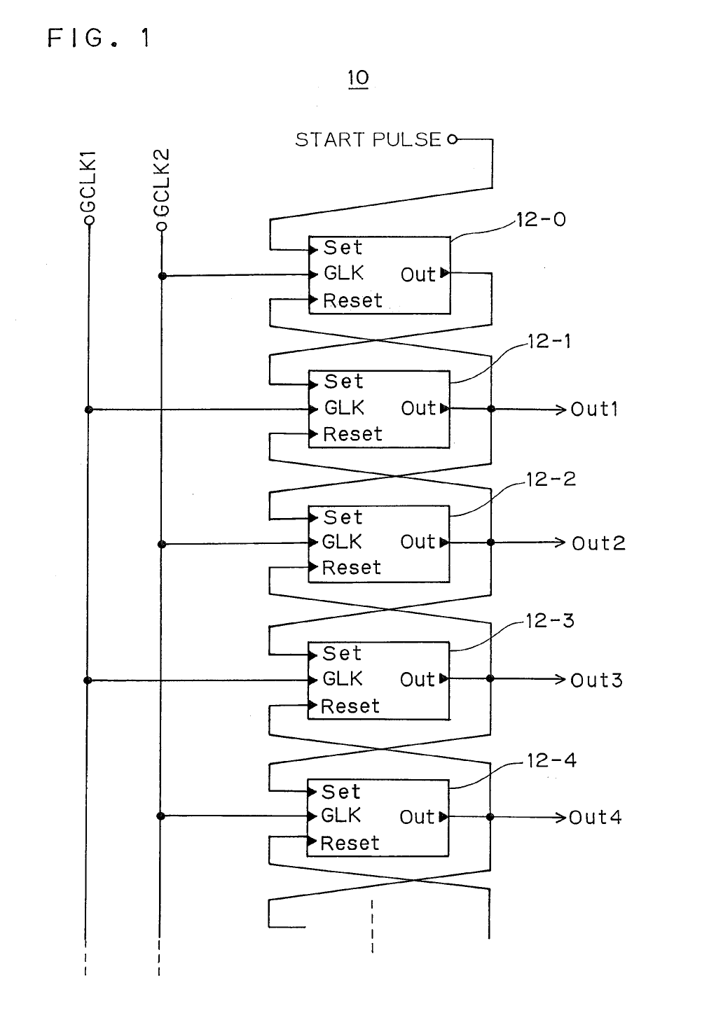

A shift register circuit 10 according to an embodiment of the invention will be described based on FIGS. 1 to 3.

Disclosure in the embodiment is mere an example, and modifications which can be conceived easily by those skilled in the art without departing from the gist of the invention are included in the scope of the invention as a matter of course. In order to clarify the description, drawings may schematically illustrate respective components in terms of the width, thickness, and shape differently from the reality. However, those illustrated in the drawings are mere examples, and are not intended to limit the interpretation of the invention.

In the specification and drawings, detailed descriptions may be omitted when using components or reference numerals identical to those in drawings that have been described.

### (1) Shift Register Circuit 10

The shift register circuit 10 will be described based on FIG. 1.

The shift register circuit 10 includes N signal generating circuits 12 and the n-th (where 1≦n≦N) signal generating circuit 12-n is set by the output signal Out (n−1) of the (n−1)-th signal generating circuit 12-(n−1) and is reset by the output signal Out (n+1) of the (n+1)-th signal generating circuit 12-(n+1). The odd-numbered signal generating circuits 12 receive a clock signal GCLK1 and the even-numbered signal generating circuits 12 receive a second clock signal GCLK2.

A signal generating circuit 12-0 for starting is connected in the preceding stage of the first signal generating circuit 12, the signal generating circuit 12-0 receives the second clock signal GCLK2, and the output signal Out(0) of the signal generating circuit 12-0 for starting is output to the set terminal of the first signal generating circuit 12-1. In addition, the set terminal of the signal generating circuit 12-0 for starting receives a start pulse signal from the outside and the reset terminal receives the output signal Out(1) of the first signal generating circuit 12-1.

The shift register circuit 10 is used in the driver circuit of, for example, a liquid crystal display device and the output signals Out in the individual stages are used as gate signals for the pixels of the liquid crystal display device.

### (2) Structure of the Signal Generating Circuit 12

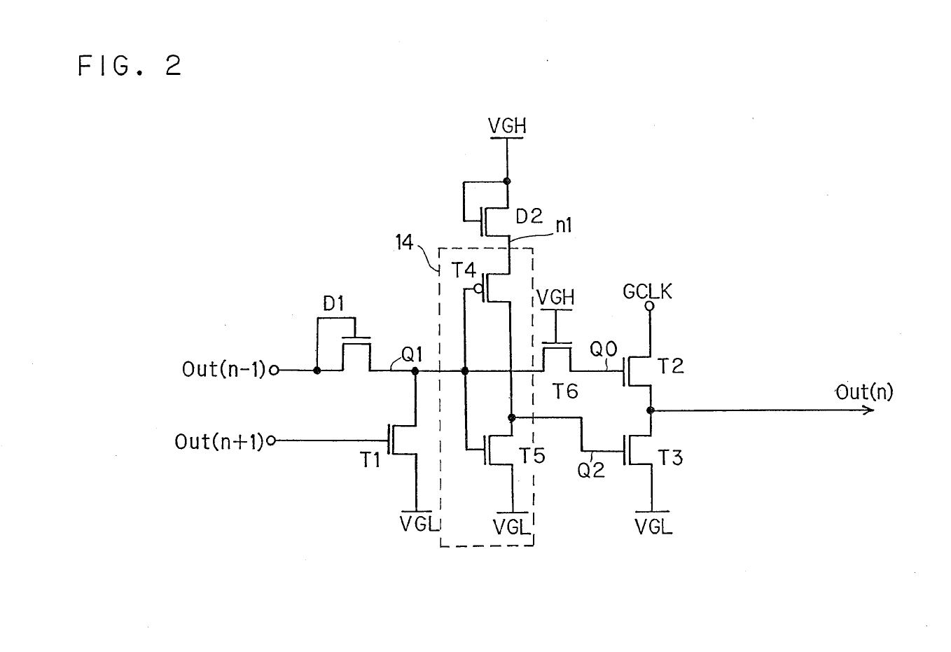

Next, the structure of the n-th signal generating circuit 12 will be described based on the circuit diagram in FIG. 2. The signal generating circuit 12 has eight elements including two diodes D1 and D2 and six transistors T1 to T6. The signal generating circuit 12-0 for starting has the same structure.

The first diode D1 is formed by diode connection of an N-channel transistor and has an anode connected to the set terminal. The set terminal receives the output signal Out(n−1) output from the signal generating circuit 12-(n−1) in the preceding stage.

The second diode D2 is formed by diode connection of an N-channel transistor and has an anode connected to a VGH power source.

The gate of the first N-channel transistor T1 is connected to the reset terminal and the reset terminal receives the output signal Out (n+1) of the signal generating circuit 12-(n+1) in the next stage. The drain of the first transistor T1 is connected to a cathode Q1 of the first diode D1 and the source is connected to a VGL power source.

The source of the second N-channel transistor T2 is connected to the output terminal and the drain is connected to a clock signal input terminal that receives the clock signal GCLK. The first clock signal GCLK1 is input when n is an odd number or the second clock signal GCLK2 is input when n is an even number.

The drain of the third N-channel transistor T3 is connected to the output terminal and the source is connected to the VGL power source.

The source of the sixth N-channel transistor is connected to a gate Q0 of the second transistor T2, the drain is connected to the cathode Q1 of the first diode D1, and the gate is connected to the VGH power source. Here, VGH>VGL holds.

A CMOS inverter circuit 14 is formed by the fourth P-channel transistor T4 and the fifth N-channel transistor T5. The CMOS inverter circuit 14 is a logic inverting circuit having a gate structure in which a P-channel MOSFET and an N-channel MOSFET are disposed in a complementary shape. In the CMOS inverter circuit 14, the drains of the fourth P-channel transistor T4 and the fifth-channel transistor T5 are connected to each other to form an output point and the gates are connected to each other to form an input point. In addition, the source of the fourth transistor T4 is a high potential connection point and the source of the fifth transistor T5 is a low potential connection point. The input point of the CMOS inverter circuit 14 is connected to the cathode Q1 of the first diode D1, the output point is connected a gate Q2 of the third N-channel transistor T3, the high potential connection point is connected to the cathode of the second diode D2, and the low potential connection point is connected to the VGL power source.

When a Q1 node, which is the input side of the CMOS inverter circuit 14, has the same potential as VGL, the fourth transistor T4 turns on and the fifth transistor T5 turns off. Therefore, the potential of a Q2 node is substantially equal to (VGH−Vth). Vth is the threshold voltage of the transistor.

In addition, when the Q1 node has the same potential as (VGH−Vth), the fourth transistor T4 turns off and the fifth transistor T5 turns on. Accordingly, the potential of the Q2 node, which is the output side, is substantially equal to VGL. That is, the potential opposite to that of the Q1 node appears at the Q2 node.

The switching of the second transistor T2 uses a bootstrap by the clock signal GCLK and the switching is performed by a rise in the potential of the Q0 node coupled with a change in the potential of the clock signal GCLK. Although the potential of the Q0 node becomes 2(VGH−VGL) at the timing of a gate output, the sixth transistor T6 is added for the purpose of breakdown voltage protection to prevent a high voltage exceeding (VGH−VGL) from being applied to the second transistor T2 and the like.

The H level of the cathode Q1 node of the first diode D1 becomes (VGH−Vth) by reduction of the threshold voltage Vth of the transistor. The first transistor T1 is provided to make connection with the cathode Q1 of the first diode D1 when (n+1)-th output signal Out (n+1) becomes the H level.

By adding the second diode D2 so that the potential of the high potential connection point of the CMOS inverter circuit 14 formed by the fourth transistor T4 and the fifth transistor T5 becomes (VGH−Vth) instead of the VGH power source, the fourth transistor T4 can be turned off reliably at the H level of the Q node and a through current passing through the fourth transistor T4 and the fifth transistor T5 can be prevented.

### (3) Operation of the Signal Generating Circuit 12

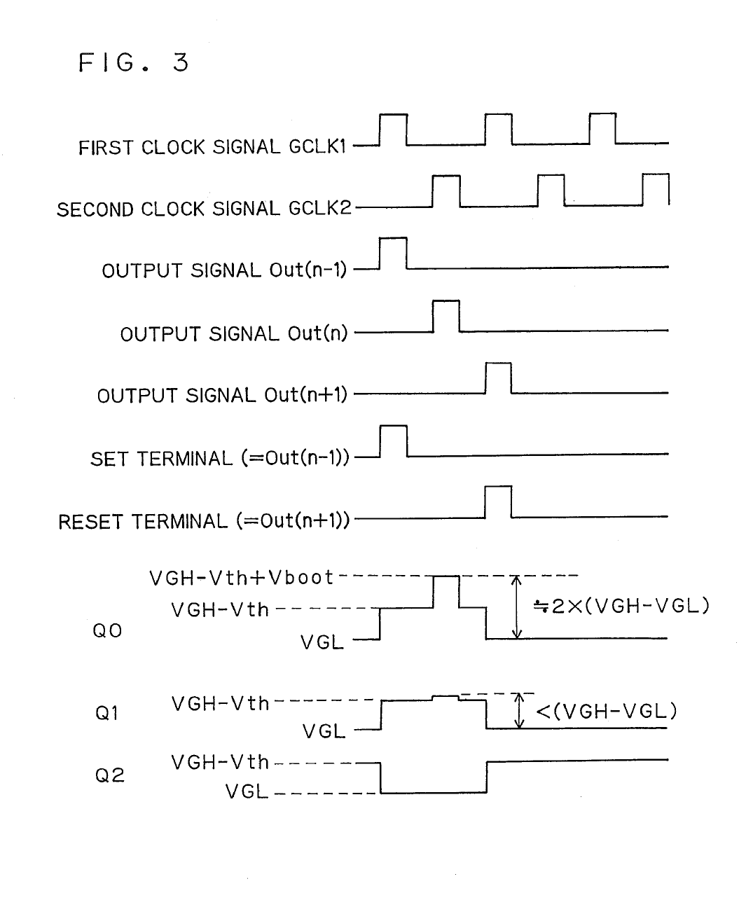

Next, the operation of the n-th signal generating circuit 12 will be described based on the circuit diagram in FIG. 2 and the waveform diagram in FIG. 3. It is assumed that the second clock signal GCLK2 is input as the clock signal GCLK.

In the waveform diagram, the first line indicates the first pulsed clock signal GCLK1 and the second line indicates the second pulsed clock signal GCLK2.

The third line in the waveform diagram indicates the output signal Out(n−1) of the (n−1)-th signal generating circuit 12, the fourth line indicates the output signal Out(n) of the n-th signal generating circuit 12, and the fifth line indicates the output signal Out (n+1) of the (n+1)-th signal generating circuit 12.

The sixth line in the waveform diagram indicates the output signal Out(n−1) input to the set terminal of the n-th signal generating circuit 12 and the seventh line indicates the output signal Out(n+1) input to the reset terminal.

In the operation time from when the set terminal receives the output signal Out(n−1) in the preceding stage to set the signal generating circuit to when the reset terminal receives the output signal Out(n+1) in the next stage to reset the signal generating circuit, the voltage (VGH−Vth) is applied to the Q0 node in the eighth line in the waveform diagram and, only when the second clock signal GCLK2 is input, the voltage value becomes (VGH−Vth+Vboot) by a bootstrap. The voltage Vboot is the same as the voltage value of the second clock signal GCLK2. The voltage (VGH−Vth+Vboot) is substantially the same as 2(VGH−VGL).

Similarly, in the operation time, the voltage of the Q1 node in the ninth line in the waveform diagram becomes (VGH−Vth) and this potential difference is smaller than (VGH−VGL).

Similarly, the voltage of the Q2 node in the tenth line in the waveform diagram drops from (VGH−Vth) to VGL.

This combines the potential of the Q0 node with the potential of the Q2 node and the pulsed output signal Out(n) is output from the output terminal.

### (4) Effect

In the embodiment, since the number of elements in each stage of the signal generating circuits 12 is eight, the circuit layout area is small, thereby achieving the narrow frame during application to the driver circuit of a liquid crystal display device.

### (5) Modifications

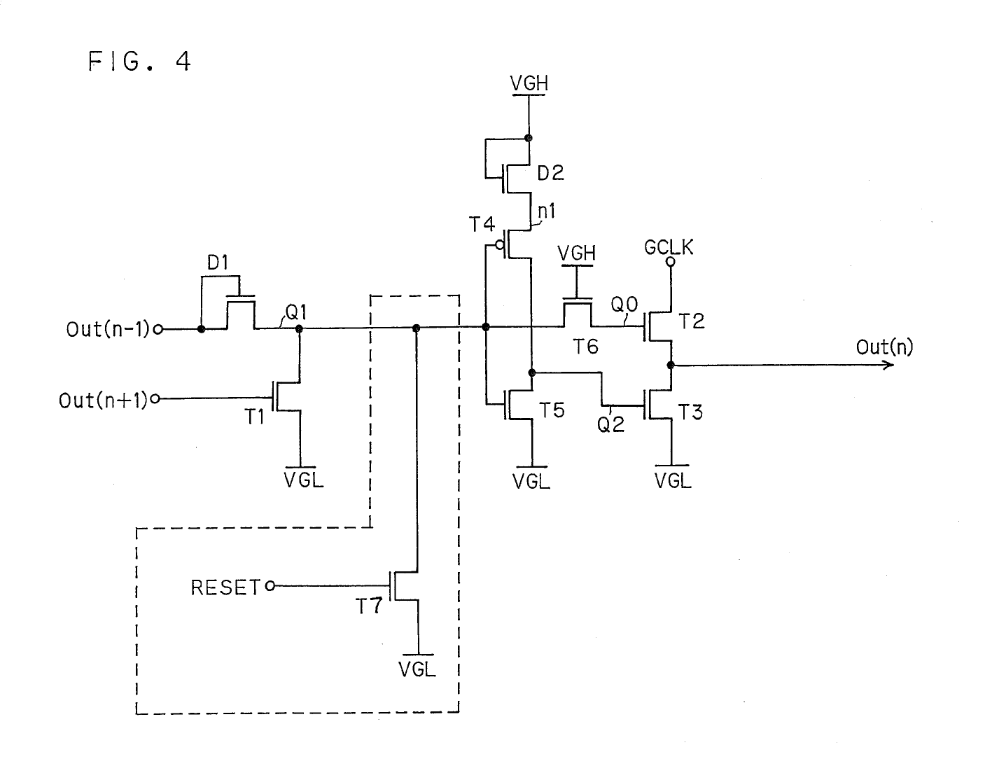

Modifications of the shift register circuit 10 will be described based on FIG. 4. The modifications are different from the above embodiment in that the drain of a seventh N-channel transistor T7 is connected to the cathode Q1 of the first diode D1, the source of the seventh transistor T7 is connected to the VGL power source, and the gate is connected to the reset terminal, in the signal generating circuit 12 in each stage.

The seventh transistor T7 is connected to prevent the undefined state of the Q1 node during power-on. That is, the reset terminal receives a reset signal that becomes the H level during power-on and the L level during normal driving. This reset signal can be used to fix the Q1 node at the VGL potential. The seventh transistor T7 functions as a reset switch.

Although the first transistor T1, the second transistor T2, the third transistor T3, the fifth transistor T5, and the sixth transistor T6 are N-channel transistors and the fourth transistor T4 is a P-channel transistor in the above embodiment, it is also possible to form the first to third transistors T1 to T3 and the fifth and sixth transistors T5 and T6 as P-channel transistors and the fourth transistor T4 as an N-channel transistor instead of a P-channel transistor. In this case, the VGH power source and the VGL power source are reversely connected.

In addition, all embodiments that can be devised by those skilled in the art through appropriate design changes based on the embodiment of the invention belong to the scope of the invention as long as the embodiments include the spirit of the invention.

In the category of the thought of the invention, those skilled in the art may imagine various modifications and corrections, and these modifications and corrections are considered to be included within the scope of the invention. For example, those in which components have been added or deleted or the design has been changed as appropriate by those skilled in the art, or those in which processes have been added or omitted, or the conditions have been changed may be included within the range of the invention as long as the gist of the invention is included.

Those apparent from the description of the specification or imagined easily by those skilled in the art of other advantageous effects generated by the configuration described in the embodiment are considered to be generated by the invention as a matter of course.

While certain embodiments have been described, these embodiments have been presented by way of example only, and are not intended to limit the scope of the inventions. Indeed, the novel embodiments described herein may be embodied in a variety of other forms; furthermore, various omissions, substitutions, and changes in the form of the embodiments described herein may be made without departing from the spirit of the inventions. The accompanying claims and their equivalents are intended to cover such forms or modifications as would fall within the scope and spirit of the inventions.

What is claimed is:

1. A shift register circuit comprising:
N signal generating circuits each configured to generate a pulsed output signal, the n-th (where 1≦n≦N) signal generating circuit of the N signal generating circuits including
a set terminal configured to receive an output signal of the (n−1)-th signal generating circuit,
a first diode having an anode connected to the set terminal,
a reset terminal configured to receive an output signal of the (n+1)-th signal generating circuit,
a first N-channel transistor having a gate connected to the reset terminal, the first N-channel transistor configured to connect a cathode of the first diode to a low potential power source when the output signal of the (n+1)-th signal generating circuit is input to the gate,
a second N-channel transistor having a source connected to an output terminal and a drain configured to receive a clock signal,
a third N-channel transistor having a source connected to the low potential power source and a drain connected to the output terminal,
a CMOS inverter circuit that includes a fourth P-channel transistor and a fifth N-channel transistor,
a sixth N-channel transistor having a source connected to a gate of the second transistor, a drain connected to the cathode of the first diode, and a gate connected to a high potential power source, and
a second diode having an anode connected to the high potential power source, wherein
an input point of the CMOS inverter circuit is connected to the cathode of the first diode,
an output point of the CMOS inverter circuit is connected to a gate of the third transistor,
a high potential connection point of the CMOS inverter circuit is connected to a cathode of the second diode, and
a low potential connection point of the CMOS inverter circuit is connected to the low potential power source.

2. The shift register circuit according to claim 1, further comprising:
a seventh N-channel transistor having a gate configured to receive a reset signal during power-on, the seventh N-channel transistor configured to connect the cathode of the first diode to the low potential power source.

3. The shift register circuit according to claim 1,
wherein each of the first diode and the second diode includes an N-channel transistor that has undergone diode connection.

4. The shift register circuit according to claim 1,
wherein a signal generating circuit for starting is provided in a preceding stage of the first signal generating circuit,
the set terminal of the signal generating circuit for starting receives a start pulse,
the reset terminal of the signal generating circuit for starting receives an output signal of the first signal generating circuit, and
the output terminal of the signal generating circuit for starting is connected to the set terminal of the first signal generating circuit.

5. The shift register circuit according to claim 4,
wherein the odd-numbered signal generating circuits of the N signal generating circuits receive a first pulsed clock signal,
the signal generating circuit for starting and the even-numbered signal generating circuits receive a second pulsed clock signal, and
the second pulsed clock signal becomes a high level deviating from the first pulsed clock signal by a predetermined time.
